(19) United States
(12) Patent Application Publication
(10) Pub. No.: US 2012/0020048 A1
(43) Pub. Date: Jan. 26, 2012

(54) Shielding housing

(76) Inventor: Wilfried Hackenbroich, Holzkirchen (DE)

(21) Appl. No.: 12/931,719

(22) Filed: Feb. 8, 2011

(30) Foreign Application Priority Data
Jul. 21, 2010 (DE) 202010010507.2

(51) Int. Cl. H05K 9/00

(52) U.S. Cl. 361/818; 174/382

(57) ABSTRACT

A shielding housing has an electromagnetic closure. The housing has a base part and a lid part. The base part and the lid part may be hingedly connected to one another at a rear portion of the housing. There may also be an opening device for opening the lid.

The present invention relates to a shielding housing having a base part and a lid part.

The prior art discloses radio measurement stations or apparatuses for testing mobile telephones. Such a radio measurement station produces a test network in which a mobile telephone to be tested which is equipped with a special test SIM (Subscriber Identity Module) card can register for test purposes. The test network is operated on the basis of a mobile radio standard, e.g. the UMTS Standard. The testing of mobile telephones is therefore performed very realistically so to speak, since even in operation the mobile telephones register in an existing mobile radio network and interchange data therewith. To perform the test, a connection is set up at that time between a radio measurement station and the mobile telephone, this being able to be done either by a call from the radio measurement station on the mobile telephone or conversely by a call from the mobile telephone on the radio measurement station. Subsequently, particular test procedures or routines are performed in order to check particularly the transmission and reception capability of the mobile telephone in respect of compliance with the specifications required for proper serviceability which are prescribed by the manufacturer. By way of example, this is done by transmitting data from the radio measurement station to the mobile telephone and then transmitting them back from the mobile telephone to the radio measurement station, said data then being checked for incorruptness. Furthermore, the upshot is that measurement results for various parameters are indicated in a measurement log which can be displayed, stored and/or printed. In particular, the overall result of the test, namely “test passed” or “test not passed”, is also provided. Such radio measurement stations for testing mobile telephones have a multiplicity of applications in practice. By way of example, these are used for producing mobile telephones, e.g. for final inspection or in an intermediate step of production in the factory in which mobile telephones are manufactured. An intermediate step of this kind is used for aligning components, for example. Every mobile telephone produced should be tested prior to delivery, which means that this final test is a bottleneck for the overall manufacturing process on account of the time required for this. This is because the mobile telephones are tested individually and successively at a measurement station. A further application for such radio measurement stations is use thereof in what are known as service centers, to which faulty or allegedly faulty mobile telephones are sent for repair. In this case, it is important first of all to establish whether the mobile telephones are actually faulty and to analyze whether and in what way, for example by replacing a particular component, they can be repaired. Such service centers frequently test a multiplicity of mobile telephones of different types and from different manufacturers, specifically firstly when they arrive at the service center and secondly also after they have been repaired. Finally, such radio measurement stations are also used in the development of mobile telephones by the manufacturers.

In principle, the radio link between radio measurement station and mobile telephone can be made using appropriate RF cable. In practice, however, it has become common to make the connection between radio measurement station and mobile telephone via the air interface, so that the radio measurement station is connected in test mode to an antenna coupler which has an antenna which can couple to the antenna of the mobile telephone. Mobile telephones are therefore tested very realistically. The radio measurement station together with the antenna coupler is a small test base station, the particular advantage in this case being that the antenna of the mobile telephone and the components connected upstream and downstream thereof are tested together. Examples of such antenna couplers are described in the German Patent Specification DE 197 32 639 C1 and the German Laid-Open specifications DE 103 56 087 A1 and DE 10 2004 033 383 A1 from the present applicant, the entire disclosure content of which is incorporated into the present application by means of this reference.

In order to shield the RF measurement from interfering ambient influences, e.g. from actually existing mobile radio networks, the antenna coupler and the mobile telephone to be tested are inserted into a shielding housing during the test. An example of such a shielding housing is described in the German Patent Specification DE 10 2004 049 354 B4 from the present applicant, the full content of the disclosure of which is likewise incorporated into the present application by means of this reference.

Such shielding housings have the particular problem that the housing needs to be sealed so as to be as impermeable to RF as possible in order to create an interference-free test environment in the interior of the housing. To this end, the prior art makes use of strong closing mechanisms, which are difficult to use in practice, however. Particularly women as service operatives often do not have sufficient strength to seal the shielding housing repeatedly at the beginning of a test throughout the day. Besides fatigue, another problem in this case is that the test result obtained may be corrupt if the shielding housing is not complete.

The invention is therefore based on the object of avoiding the drawbacks of the prior art, and particularly of developing a shielding housing of the type cited at the outset such that RF-impermeable closure of a shielding housing is possible in a simple manner.

This object is achieved for a shielding housing of the type cited at the outset by virtue of the shielding housing having an electromagnetic closure.

One advantage of the present invention is that the invention allows electrical actuation of the closing mechanism. By way of example, the shielding housing can be automatically opened following completion of the test by opening the electromagnetic closure. It is also possible to sense the opening and closing state of the shielding housing, so that, by way of example, the test on a mobile telephone which is to be tested is not started until a closed state of the shielding housing has been sensed.

Further preferred embodiments of the invention are disclosed in the dependent patent claims.

The invention, and further features, aims, advantages and application options thereof, is and are explained in more detail below using a description of preferred exemplary embodiments with reference to the appended drawings. In the drawings, the same reference symbols denote the same or corresponding elements. In the present description, the expressions “front”, “rear”, “left” and “right” and related expressions are used which relate to a position of a user when using the shielding housing, wherein the user is arranged in front of the shielding housing during operation thereof, so that in the closed state of the shielding housing the user is able to look into the interior of the housing and the user is faced by the operator control device and the handle of the shielding housing. In this case, all features described and/or graphically illustrated form the subject matter of the present invention in their own right or in any meaningful combination, specifically irrespective of how they are combined in the claims or their back-references. In the drawings:

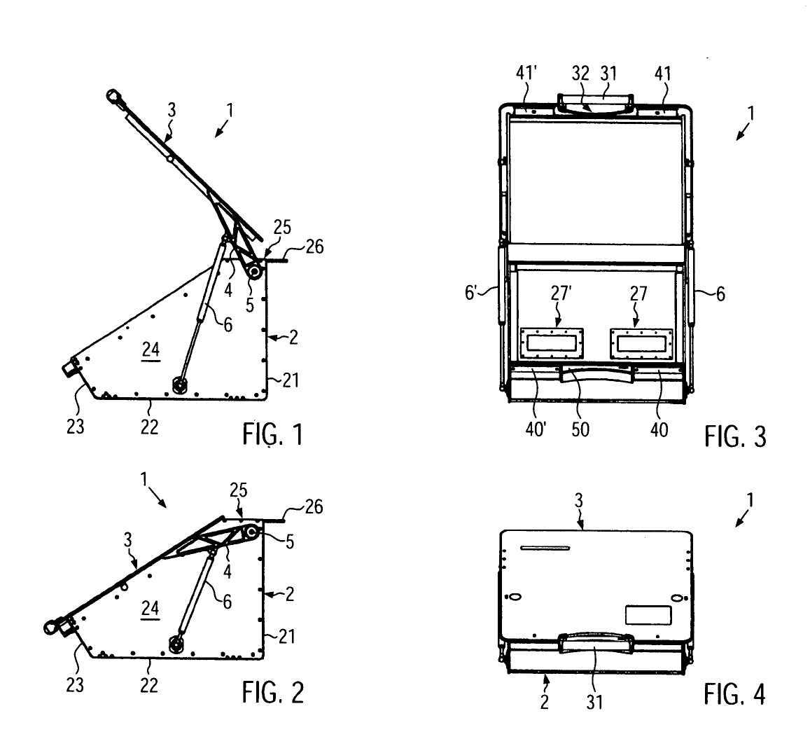

FIG. 1 shows a schematic side view of an exemplary embodiment of the shielding housing according to the invention in the opened state;

FIG. 2 shows a schematic side view of the exemplary embodiment of the shielding housing according to the invention in the closed state;

FIG. 3 shows a schematic front view of the exemplary embodiment of the shielding housing according to the invention in the opened state;

FIG. 4 shows a schematic front view of the exemplary embodiment of the shielding housing according to the invention in the closed state; and

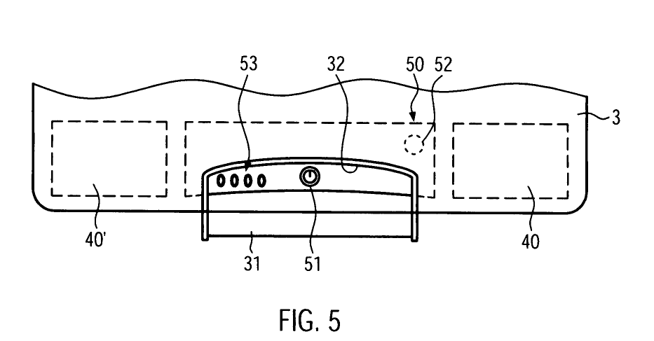

FIG. 5 shows a schematic top view of the front part of the shielding housing according to the invention in the closed state.

The schematic illustrations of FIGS. 1 to 4 are subsequently used to provide a more detailed explanation of a preferred exemplary embodiment of a shielding housing according to the invention, the whole of which is denoted by the reference symbol 1. The shielding housing 1 has a base part 2 and a lid part 3. In a sectional direction from front to rear (cf. the side views of FIGS. 1 and 2), the base part 2 has an essentially vertical back wall 21, an essentially horizontal base wall 22 and a forwardly inclined front wall 23. In said sectional direction from front to rear, the base part is therefore essentially U-shaped, with the front limb (front wall 23) of the U being shortened and forwardly inclined. In addition, the base part has left and right side walls, FIGS. 1 and 2 showing only the right side wall 24. The rear upper end section of the base part 2 has an essentially horizontal upper wall 25, a rear section 26 of which projects or protrudes rearward beyond the back wall 21 of the base part 2. The section 26 does not extend over the entire width of the shielding housing 2, but rather is merely provided in the center thereof and has a recess (not shown) through which the section 26 serves as a carrying handle for the shielding housing 1.

The lid part 3 is connected to a left and right jib (FIGS. 1 and 2 show only the right jib 4) which is connected to left and right pivots (FIGS. 1 and 2 show only the right pivot 5). Left and right gas compression springs 6, 6′ (cf. FIG. 3) keep the shielding housing open. For this purpose, the lower end of the gas compression spring 6 is mounted on a lower outer region of the side wall 24, and the upper end of the gas compression spring 6 is mounted on the jib 4. The gas compression spring 6′ is mounted on the opposite side in corresponding fashion.

The lid part 3 is essentially a flat plate and has, at its front end, a handle 31 which can be grasped through a recess 32 which is formed approximately centrally in the front edge of the lid part 3. The handle 31 is arranged outside of the front edge of the lid part 3, and the recess 32 extends into the front edge of the lid part 3 (cf. FIG. 3). A user can then close the shielding housing 1 against the pressure of the gas compression spring 6′ and 6 by grasping the handle 31 of the lid part 3, with the edge regions of the base part 2 and of the lid part 3—which edge regions face one another and are in contact with one another—being sealed so as to be impermeable to RF in the closed state as a result of appropriate profiling and material selection, so that a miniature measurement chamber is formed inside the shielding housing 1, i.e. in the interior of the base part 2. The rear wall 21 of the base part 2 of the shielding housing 1 is provided with two apertures 27′, 27 (cf. FIG. 3), with appropriate connections being able to be provided on the latter in order to supply signals (e.g. test signals for testing mobile telephones) to and from the closed shielding housing 1. The front edge of the base part 2, and more precisely the outer upper end of the front wall 23, is provided with two electromagnets 40′ and 40. Appropriate points in the lid part are provided with counterplates 41′ and 41 comprising magnetic or magnetizable materials. The electromagnets 40′, 40 together with the counterplates 41′, 41 form an electromagnetic closure for the shielding housing 1. The relative arrangement of the electromagnets 40′ and 40 with respect to the counterplates 41′ and 41 is such that in the closed state of the shielding housing 1, i.e. when the lid part 3 is depressed against the initial tension of the gas compression springs 6, 6′, the counterplate 41′ is in contact with the electromagnet 40′ and the counterplate 41 is in contact with the electromagnet 40. The counterplates 41′ and 41, are respectively arranged on the left and right of the handle 31. To be more precise, the counterplates 41′ and 41 have the recess 32 provided between them. The electromagnets 40′ and 40 have an operator control device 50 provided between them. Even in the closed state of the shielding housing 1, i.e. when the lid part 3 is closed, the top of the operator control device 50 is partially accessible to a user through the recess 32 in the lid part 3, as will be explained in more detail below with reference to FIG. 5.

The schematic illustration in FIG. 5 shows that the operator control device 50 has a pushbutton switch 51 which can activate or operate the electromagnetic closure, i.e. the electromagnets 40′, 40 are energized, and in the closed state of the lid part 3, the shielding housing is therefore very tightly sealed.

This is based on the attracting effect of the energized electromagnets 40′, 40 on the counterplates 41′ and 41.

In addition, the operator control device 50 has a sensor 52 in the form of a photodiode. Whereas, in the closed state, i.e. with the lid part 3 folded down, the pushbutton switch 51 is accessible through the recess 32 in the lid part 3, the sensor 52 is concealed by the lid part 3 in the closed state. The sensor 52 is provided for the purpose of sensing a sufficiently closed state of the lid part 3, and in response to an appropriate threshold value, i.e. when the ambient light sensed by the sensor 52 becomes sufficiently weak, specifically as a result of the lid part 3 closed above it, the electromagnets 40′ and 40 are activated. In this case, activation of the operation of the electromagnets 40′, 40 means that the latter are energized, and hence attract the counterplates 41′, 41, which are not shown in FIG. 5, so that the lid part 3 of the shielding housing 1 is pushed further closed by the electromagnetic closure, and the shielding housing 1 is sealed with a first degree of closing. This first degree of closing, i.e. the current level for the electromagnets 40′, 40 which is produced when the sensor 52 is activated, is still not sufficient to provide sufficient RF shielding of the inside of the shielding housing for test purposes, however. Only upon manual operation of the pushbutton switch 51 are the electromagnets 40′, 40 supplied with a higher current level, and the shielding housing 1 is then closed to a second, greater degree of closing so as to be impermeable to RF. It is now possible to begin a measurement on a mobile telephone and the like which has been inserted into the shielding housing, for example in an antenna coupler.

In addition, the operator control device 50 has an indicator device 53, which preferably comprises various LED signal lamps. There may therefore be a light-emitting diode provided which indicates the on/off state of the shielding housing 1, another light-emitting diode can indicate an error message, a further light-emitting diode can indicate the degree of closing of the shielding housing, etc.

The invention has been explained in more detail above using preferred embodiments thereof. However, it is clear to a person skilled in the art that various alterations and modifications can be made without departing from the concept on which the invention is based.

1. A shielding housing having a base part and a lid part, wherein the shielding housing has an electromagnetic closure.

2. The shielding housing as claimed in claim 1, wherein the base part and the lid part are hinged to one another at a rear region of the shielding housing.

3. The shielding housing as claimed in claim 1 or 2, wherein the shielding housing has an opening device for opening the lid part.

4. The shielding housing as claimed in claim 3, wherein the opening device has at least one gas compression spring.

5. The shielding housing as claimed in one of claims 1 to 4, wherein the electromagnetic closure has at least two electromagnets.

6. The shielding housing as claimed in claim 5, wherein the at least two electromagnets are arranged in the base part of the shielding housing.

7. The shielding housing as claimed in claim 5 or 6, wherein the at least two electromagnets are arranged at the upper edge of the base part of the shielding housing.

8. The shielding housing as claimed in one of claims 5 to 7, wherein the at least two electromagnets are arranged at the front of the shielding housing.

9. The shielding housing as claimed in one of claims 5 to 8, wherein the at least two electromagnets are arranged outside of the measurement chamber formed by the inside of the shielding housing in the closed state.

10. The shielding housing as claimed in one of claims 5 to 9, wherein the electromagnetic closure has at least two counterplates, corresponding to the electromagnets, comprising magnetic or magnetizable materials.

11. The shielding housing as claimed in claim 10, wherein the at least two counterplates are arranged in the lid part of the shielding housing.

12. The shielding housing as claimed in claim 10 or 11, wherein the at least two counterplates are each essentially in contact with the at least two electromagnets in the closed state of the shielding housing.

13. The shielding housing as claimed in one of claims 10 to 12, wherein the at least two counterplates are arranged at the front of the shielding housing.

14. The shielding housing as claimed in one of claims 10 to 13, wherein the at least two counterplates are arranged outside of the measurement chamber formed by the inside of the shielding housing in the closed state.

15. The shielding housing as claimed in one of claims 1 to 14, wherein the shielding housing has a sensor which senses the opening state of the shielding housing.

16. The shielding housing as claimed in one of claims 1 to 15, wherein the shielding housing has a sensor, said sensor sensoring a sufficiently closed state of the lid part.

17. The shielding housing as claimed in claim 15 or 16, wherein the sensor is a photodiode.

18. The shielding housing as claimed in one of claims 15 to 17, wherein it has a control apparatus which activates the electromagnetic closure when the sensor senses a sufficiently closed state of the lid part.

19. The shielding housing as claimed in claim 18, wherein the control apparatus deactivates the electromagnetic closure after the end of a measurement on a mobile telephone.

20. The shielding housing as claimed in one of claims 1 to 19, wherein the base part has an operator control device.

21. The shielding housing as claimed in claim 20, wherein the operator control device has a switch in order to activate the electromagnetic closure.

22. The shielding housing as claimed in claim 21, wherein the activation of the electromagnetic closure by the switch is stronger than the activation of the electromagnet by the sensor.

23. The shielding housing as claimed in one of claims 20 to 22, wherein the front edge of the lid part has a handle formed by a recess, with the operator control device being in contact with the handle in the closed state of the shielding housing, with part of the operator control device being accessible through the recess in the closed state of the shielding housing, and another part of the operator control device being concealed by the lid part.

24. The shielding housing as claimed in one of claims 20 to 23, wherein the at least two electromagnets are arranged on both sides of the operator control device.

25. The shielding housing as claimed in one of claims 20 to 24, wherein the switch is arranged on one part of the operator control device.

26. The shielding housing as claimed in one of claims 20 to 25, wherein the sensor is arranged on the other part of the operator control device.

27. The shielding housing as claimed in one of claims 20 to 26, wherein at least one indicator device for indicating the status of the electromagnetic closure is arranged on one part of the operator control device.

28. The shielding housing as claimed in one of claims 1 to 27, wherein the base part is essentially U-shaped in section from front to rear.

29. The shielding housing as claimed in claim 28, wherein the U-shape is such that the front limb of the U-shape is shorter than the rear limb of the U-shape.

30. The shielding housing as claimed in claim 29, wherein the U-shape is such that the front limb of the U-shape is inclined forward.

31. The shielding housing as claimed in one of claims 1 to 30, wherein the lid part is an essentially flat plate.
